(19) United States
(12) Patent Application Publication
(10) Pub. No.: US 2010/0075107 A1
(43) Pub. Date: Mar. 25, 2010

(54) HEXAGONAL WURTZITE SINGLE CRYSTAL AND HEXAGONAL WURTZITE SINGLE CRYSTAL SUBSTRATE

(75) Inventors: Makoto Saito, Santa Barbara, CA (US); Steven P. DenBaars, Goleta, CA (US); James S. Speck, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/474,134

(22) Filed: May 28, 2009

Related U.S. Application Data
(60) Provisional application No. 61/056,797, filed on May 28, 2008.
(60) Provisional application No. 61/112,560, filed on Nov. 7, 2008.
(60) Provisional application No. 61/112,552, filed on Nov. 7, 2008.
(60) Provisional application No. 61/112,558, filed on Nov. 7, 2008.
(60) Provisional application No. 61/112,545, filed on Nov. 7, 2008.
(60) Provisional application No. 61/112,550, filed on Nov. 7, 2008.

(51) Int. Cl. C01B 21/06; B32B 5/00; C30B 23/00

(52) U.S. Cl. 428/141; 423/409; 117/84

(57) ABSTRACT

A technique for growing high quality bulk hexagonal single crystals using a solvo-thermal method, and a technique for achieving the high quality and high growth rate at the same time. The crystal quality strongly depends on the growth planes, wherein a nonpolar or semipolar seed surface such as {10-10}, {10-11}, {10-1-1}, {10-12}, {10-1-2}, {11-20}, {11-22}, {11-2-2} gives a higher crystal quality as compared to a c-plane seed surface such as (0001) and (000-1). Also, the growth rate strongly depends on the growth planes, wherein a semipolar seed surface such as {10-12}, {10-1-2}, {11-22}, {11-2-2} gives a higher growth rate. High crystal quality and high growth rate are achievable at the same time by choosing the suitable growth plane. The crystal quality also depends on the seed surface roughness, wherein high crystal quality is achievable when the nonpolar or semipolar seed surface RMS roughness is below 100 nm; on the other hand, the crystal grown from the Ga-face or N-face results in poor crystal quality, even though grown from an atomically smooth surface.

### CROSS-REFERENCE TO RELATED APPLICATIONS

This application claims the benefit under 35 U.S.C. 119(e) of the following co-pending and commonly-assigned U.S. patent application:

U.S. Patent Application Ser. No. 61/056,797, filed on May 28, 2008, by Makoto Saito et al., entitled “HEXAGONAL WÜRTZITE SINGLE CRYSTAL AND HEXAGONAL WÜRTZITE SINGLE CRYSTAL SUBSTRATE,” which application is incorporated by reference herein.

This application is related to the following co-pending and commonly-assigned U.S. patent applications:

U.S. Provisional Patent Application Ser. No. 60/790,310, filed Apr. 7, 2006, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” by Tadao Hashimoto, et al., Attorney Docket No. 30794.0179USP1;

U.S. patent application Ser. No. 11/765,629, filed on Jun. 20, 2007, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Provisional Patent Application Ser. No. 60/821,558, filed on Aug. 4, 2006, by Frederick F. Lange, Jin Hyeok Kim, Daniel B. Thompson and Steven P. DenBaars, entitled “HYDROTHERMAL SYNTHESIS OF TRANSPARENT CONDUCTING ZnO HETEROEPITAXIAL FILMS ON GaN IN WATER AT 90 C,” attorney's docket number 30794.192-US-P1 (2007-048-1);

U.S. Provisional Patent Application Ser. No. 60/911,213, filed on Apr. 11, 2007, by Frederick F. Lange, Jin Hyeok Kim, Daniel B. Thompson and Steven P. DenBaars, entitled “HYDROTHERMAL SYNTHESIS OF TRANSPARENT CONDUCTING ZnO HETEROEPITAXIAL FILMS ON GaN IN WATER AT 90 C,” attorney's docket number 30794.192-US-P2 (2007-048-2);

U.S. Provisional Patent Application Ser. No. 61/112,560, filed on Nov. 7, 2008, by Siddha Pimputkar et al., entitled “REACTOR DESIGNS FOR USE IN AMMONOTHERMAL GROWTH OF GROUP-III NITRIDE CRYSTALS,” attorney's docket number 30794.296-US-P1 (2009-283-1);

U.S. Provisional Patent Application Ser. No. 61/112,552, filed on Nov. 7, 2008, by Siddha Pimputkar et al., entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

U.S. Provisional Patent Application Ser. No. 61/112,558, filed on Nov. 7, 2008, by Siddha Pimputkar et al., entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS TO OFFSET THE DECOMPOSITION OF THE NITROGEN-CONTAINING SOLVENT AND/OR MASS LOSS DUE TO DIFFUSION OF HYDROGEN OUT OF THE CLOSED VESSEL,” attorney's docket number 30794.298-US-P1 (2009-286-1);

U.S. Provisional Patent Application Ser. No. 61/112,545, filed on Nov. 7, 2008, by Siddha Pimputkar et al., entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1);

U.S. Provisional Patent Application Ser. No. 61/112,550, filed on Nov. 7, 2008, by Siddha Pimputkar et al., entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1); and

U.S. Patent Application Ser. No. 61/855,591, filed on May 28, 2008, by Makoto Saito et al., entitled “HEXAGONAL WÜRTZITE TYPE EPITAXIAL LAYER POSSESSING A LOW ALKALI-METAL CONCENTRATION AND METHOD OF CREATING THE SAME,”

all of which applications are incorporated by reference herein.

### BACKGROUND OF THE INVENTION

1. Field of the Invention

The present invention relates to hexagonal würtzite type bulk single crystals, and more specifically, to the high speed and high quality solvo-thermal growth of hexagonal würtzite type single crystals.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The usefulness of gallium nitride (GaN) and its ternary and quaternary compounds incorporating aluminum and indium (AlGaN, InGaN, AlInGaN) has been well established for fabrication of visible and ultraviolet optoelectronic devices and high-power electronic devices. These devices are typically grown epitaxially using growth techniques including molecular beam epitaxy (MBE), metalorganic chemical vapor deposition (MOCVD), and hydride vapor phase epitaxy (HVPE).

GaN and its alloys are the most stable in the hexagonal würtzite crystal structure, in which the structure is described by two (or three) equivalent basal plane axes that are rotated 120° with respect to each other (the a-axis), all of which are perpendicular to a unique c-axis. Group III and nitrogen atoms occupy alternating c-planes along the crystal's c-axis. The symmetry elements included in the würtzite structure dictate that III-nitrides possess a bulk spontaneous polarization along this c-axis, and the würtzite structure exhibits piezoelectric polarization.

Current nitride technology for electronic and optoelectronic devices employs nitride films grown along the polar c-direction. However, conventional c-plane quantum well structures in III-nitride based optoelectronic and electronic devices suffer from the undesirable quantum-confined Stark effect (QCSE), due to the existence of strong piezoelectric and spontaneous polarizations. The strong built-in electric fields along the c-direction cause spatial separation of electrons and holes that in turn give rise to restricted carrier recombination efficiency, reduced oscillator strength, and red-shifted emission.

One approach to eliminating or reducing the spontaneous and piezoelectric polarization effects in GaN optoelectronic devices is to grow the devices on non-polar or semi-polar planes of the crystal. Recently, several reports have been published which confirmed the benefit of the non-polar and semi-polar devices. Most of them indicate that high-quality substrate is essential for these device fabrications. Historically, there were many efforts using foreign substrate such as SiC, spinel, sapphire, etc. to fabricate devices; however, the device quality was poor due to the high defect density caused by hetero-epitaxy.

In this situation, high quality and high cost-performance GaN substrates for homo-epitaxy is the key material for the industrialization of non-polar and semi-polar devices. To use HVPE with GaN substrates is one approach to realize high quality non-polar or semi-polar devices, but wafer size is limited and production costs are quite high.

Moreover, growth of III-nitride crystal in supercritical ammonia has been proposed. This method has advantages as compared to conventional, HVPE-grown, GaN substrates, such as substrates that are strain free and bow free, lower defect density, cost effective processes, etc. However, there are still problems with this method, such as low growth rates, poor crystal quality, etc.

Consequently, there remains a need in the art for improved techniques of growing high quality, bulk, hexagonal würtzite single crystals. The present invention satisfies this need.

### SUMMARY OF THE INVENTION

To overcome the limitations in the prior art described above, and to overcome other limitations that will become apparent upon reading and understanding the present specification, the present invention describes a technique for growing high quality, bulk, hexagonal würtzite single crystals using a solvo-thermal method. This technique achieves both high quality and a high growth rate at the same time.

Crystal quality strongly depends on the growth planes. In the present invention, nonpolar or semipolar seed surfaces, such as {10-10}, {10-11}, {10-1-1}, {10-12}, {10-1-2}, {11-20}, {11-22}, or {11-2-2}, result in a higher crystal quality as compared to c-plane seed surfaces, namely (0001) and (000-1). Also, the growth rate strongly depends on the growth planes. Semipolar seed surfaces, such as {10-12}, {10-1-2}, {11-22}, or {11-2-2}, result in higher growth rates. Both high quality and high growth rates are achievable at the same time by choosing a suitable growth plane.

Crystal quality also depends on seed surface roughness. High quality crystals are achievable when the nonpolar or semipolar seed surface's root mean square (RMS) roughness is below 100 nm. On the other hand, a crystal grown from a Ga-face or N-face results in poor crystal quality, even though grown from an atomically smooth surface.

The term “non-polar planes” can be used to refer to a wide variety of planes that possess two nonzero h, i, or k Miller indices; and wherein the 1 Miller index is zero.

The term “semi-polar planes” can be used to refer to a wide variety of planes that possess two nonzero h, i, or k Miller indices; and a nonzero 1 Miller index.

The growth rate strongly depends on the off-orientation from the on-axis m-plane. The present invention has investigated on-axis m-plane (10-10), and the following off-orientations from the on-axis m-plane (10-10): 2 degrees towards c+/c−, 5 degrees towards c+/c−, 28 degrees towards c+/c− (10-11)/(10-1-1), 47 degrees towards c+/c− (10-12)/(10-1-2), and 90 degrees towards c+/c− (0001)/(000-1). Higher growth rate was observed using seeds which have larger off-orientation from the on-axis m-plane (10-10).

Also, the crystal quality strongly depends on the off-orientation from on-axis planes. 2 degrees off-oriented seed crystals showed the narrowest FWHM value of the XRD rocking curve measurement. On the other hand, 90 degree off-oriented (0001)/(000-1) seed crystals showed the largest FWHM.

High crystal quality and high growth rate are achievable at the same time by choosing suitable off-orientation angles.

The present invention describes crystals and methods for growing crystals. A single bulk crystal in accordance with the present invention comprises a hexagonal würtzite structure, wherein the single bulk crystal is grown via solvo-thermal growth using a seed having a nonpolar or semipolar plane.

Such a crystal further optionally comprises the single bulk crystal being a III-nitride, the seed for the crystal having a growth surface comprising at least one of the following planes: {10-10}, {10-11}, {10-1-1}, {10-12}, {10-1-2}, {11-20}, {11-22} or {11-2-2}, the seed for the crystal having a growth surface comprising an m-plane with an off-orientation angle, the off-orientation angle being toward a [0001] direction and the off-orientation angle being larger than 0.5 degrees and less than or equal to 48 degrees, the off-orientation angle being toward the [0001] direction and being larger than 0.5 degrees and less than 4.5 degrees, the off-orientation angle being toward a [000-1] direction, and larger than 0.5 degrees and less than 90 degrees, a root mean square (RMS) roughness of a growth surface of the seed being less than 100 nm, an x-ray diffraction (XRD) rocking curve full-width-at-half-maximum (FWHM) for the bulk crystal being smaller than 500 arcsec, the single bulk crystal being gallium nitride, and the single bulk crystal being cut to obtain a substrate.

A method of growing a single bulk crystal with a hexagonal würtzite structure in accordance with one or more embodiments of the present invention comprises performing solvo-thermal crystal growth on a seed crystal having a growth surface comprising a nonpolar plane or a semipolar plane.

Such a method further optionally comprises the single bulk crystal being a III-nitride, the growth surface comprising at least one of the following planes: {10-10}, {10-11}, {10-1-1}, {10-12}, {10-1-2}, {11-20}, {11-22} or {11-2-2}, the growth surface comprising an m-plane with an off-orientation angle, the off-orientation angle being toward a [0001] direction, larger than 0.5 degrees and less than or equal to 48 degrees, the off-orientation angle being toward the [0001] direction, is larger than 0.5 degrees and less than 4.5 degrees, the off-orientation angle being toward a [000-1] direction, is larger than 0.5 degrees and less than 48 degrees, a root mean square (RMS) roughness of the growth surface being less than 100 nm, an x-ray diffraction (XRD) rocking curve full-width-at-half-maximum (FWHM) for the bulk crystal being smaller than 500 arcsec, the bulk crystal being a gallium nitride, and the crystal being cut to obtain a substrate.

Another method of fabricating a III-nitride bulk crystal or device in accordance with one or more embodiments of the present invention comprises growing the III-nitride bulk crystal or device on a growth surface of a seed, wherein the growth surface comprises one or more nonpolar or semipolar planes, or one or more off-orientations of the nonpolar or semipolar planes, and using the growing, which is in a nonpolar, semipolar or off-oriented direction, to increase a quality, growth rate, or both a quality and growth rate, of the III-nitride bulk crystal or device.

Another method of making a III-nitride crystal in accordance with one or more embodiments of the present invention comprises growing a III-nitride bulk crystal via a solvo-thermal method, wherein the III-nitride bulk crystal is grown in a growth plane other than a c-plane, wherein the growth plane is selected based on at least one of a growth rate in the growth plane and a quality of growth in the growth plane.

### BRIEF DESCRIPTION OF THE DRAWINGS

Referring now to the drawings in which like reference numbers represent corresponding parts throughout:

FIG. 1 is a schematic of an autoclave according to an embodiment of the present invention.

FIG. 2 is a table that shows the thickness of the obtained crystals and the estimated growth rate data for each plane of the seed crystals.

FIG. 3 is a table that shows XRD rocking curve FWHM (full width at half maximum) data for each of the plane crystals.

FIG. 4 is a graph that shows the correlation between the on-axis XRD FWHM data of each seed surface and the on-axis XRD FWHM data of the obtained crystal.

FIG. 5 is a graph that shows the correlation between the RMS roughness of each seed surface and the on-axis XRD FWHM data of the obtained crystals.

FIG. 6 is a graph that shows the off-orientation dependence of growth rates.

FIG. 7 is a graph that shows XRD rocking curve FWHM data of each off-oriented seed crystal.

FIG. 8 is the 0-5 degree range close-up of FIG. 6.

FIG. 9 is the 0-5 degree range close-up of FIG. 7.

FIG. 10 illustrates a growth in accordance with one or more embodiments of the present invention.

### DETAILED DESCRIPTION OF THE INVENTION

In the following description of the preferred embodiment, reference is made to the accompanying drawings that form a part hereof, and in which is shown by way of illustration a specific embodiment in which the invention may be practiced. It is to be understood that other embodiments may be utilized and structural changes may be made without departing from the scope of the present invention.

Overview

The present invention describes a technique for growing high quality, bulk, hexagonal würtzite single crystals using a solvo-thermal method. The present invention also describes a technique for achieving a high quality and high growth rate at the same time.

Prior to the present invention, a method for growing III-nitride crystal in supercritical ammonia had been proposed. This method had been expected to produce bow-free, lower defect density, cost effective GaN substrates. However, there are still some problems such as low growth rate and poor crystal quality.

C-plane seed crystals have been used with this method. In the present invention, however, nonpolar and semipolar seed crystals were introduced for the first time, and the high capability of these planes has been demonstrated successfully.

The present invention utilizes various planes of the seed crystals in the growth process, including polar (N-face and Ga-face), nonpolar (m-plane and a-plane) and semipolar planes.

Technical Description

The present invention comprises a method of growing high quality GaN bulk crystals with high growth rate. In particular, the present invention utilizes various plane seed crystals in the growth process. For example, it is critically important to choose the suitable growth plane.

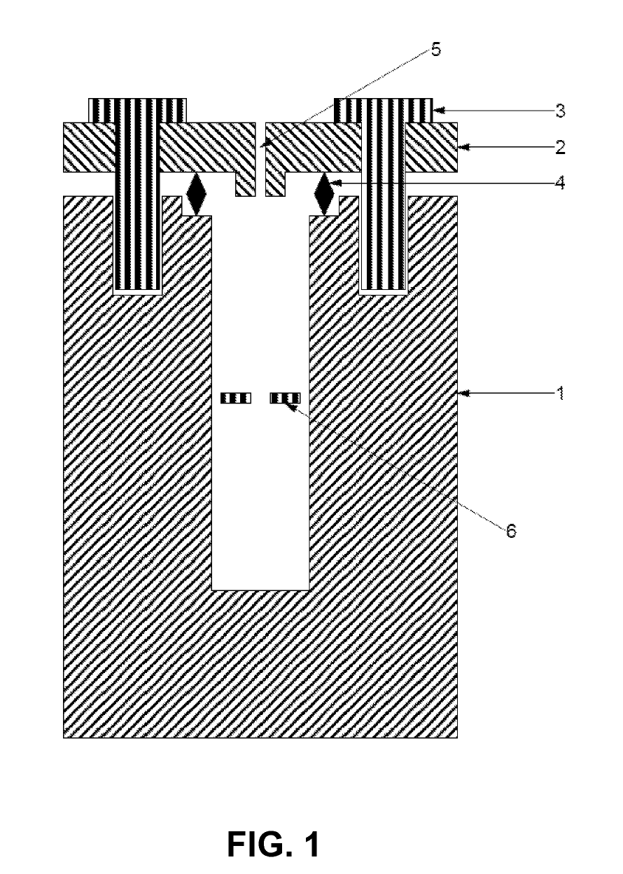

FIG. 1 is a schematic of an autoclave that may be used in an embodiment of the present invention. Included with the autoclave (1) are an autoclave lid (2), autoclave screws (3), a gasket (4), an ammonia releasing port (5), and baffle plate (6).

Preferably, the autoclave (1) is a 1-inch inner diameter autoclave, made of Ni—Cr super alloy, although other vessels may be used as well. The baffle plate (6) defines and separates a higher temperature zone of the autoclave and a lower temperature zone of the autoclave. The seed crystals mentioned above were loaded at the higher temperature zone (growth region) of the autoclave, a baffle plate (6) was set in the middle of the autoclave, and polycrystalline GaN crystals, which were contained in a Ni—Cr mesh basket, were placed at the lower temperature zone (nutrient region) of the autoclave. The nutrient polycrystalline crystals were synthesized by the HVPE method. Then, a mineralizer, sodium amide or sodium metal, was introduced into the autoclave. The lids (2) to the autoclave were closed and tightened with the necessary torque. These loading processes were all done inside a nitrogen glove box to avoid oxygen contamination.

Next, the autoclave was cooled down using liquid nitrogen. Then, ammonia was introduced into the autoclave. The amount of ammonia was monitored by a flow meter, and a high pressure valve of the autoclave was closed after the necessary amount of ammonia was condensed inside the autoclave. The amount of ammonia was strictly controlled so as to obtain necessary pressure at the growth temperature, in this case ˜200 MPa, 500˜600° C. Then, the autoclave was placed in a resistive heater system, wherein the heating system is separated into lower and upper zones, which correspond to the growth region and nutrient regions of the autoclave, respectively.

The temperature was raised using an ˜2° C. per minute rate, and was kept at 500˜550° C. for 1˜2 days to etch off the seed surface. Then, the temperature of the growth zone of the autoclave was raised again to 550˜600° C. This temperature gradient creates a solubility difference between the two regions of the autoclave, and also enhances the convection inside the autoclave for nutrient transfer. The autoclave was kept at the growth temperature for 13˜23 days (of four growths performed, for example, the maximum was 23 days and the minimum was 13 days). Then, the ammonia was released after the autoclave was returned to room temperature. Finally, the crystals were unloaded from the autoclave.

The obtained crystals were examined by micrometer for growth thickness=growth rate, and by X-ray diffraction meter for the estimation of crystal quality. The surface roughness of the seed crystal was investigated by step height measurement. The experimental results are set forth in more detail below.

Experimental Results

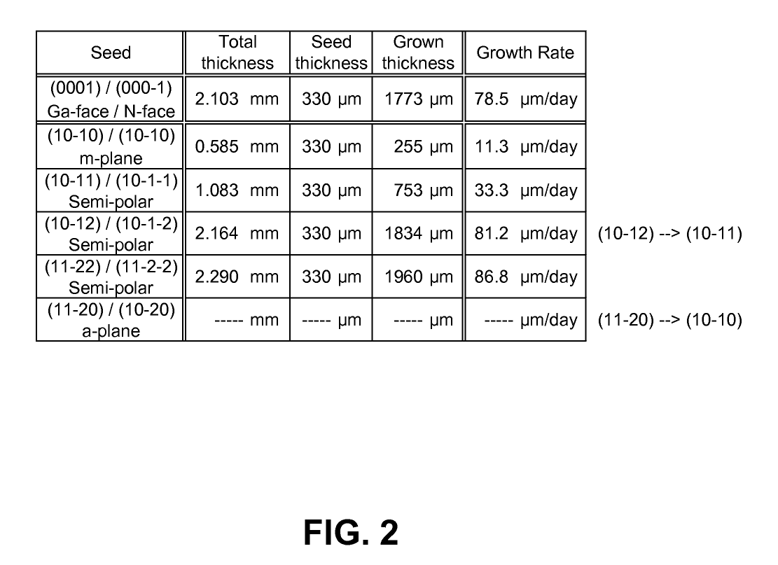

FIG. 2 is a table that shows the thickness of the obtained crystals and the estimated growth rate data for each plane of the seed crystals. The growth rate strongly depends on the growth planes. Semipolar (11-22)/(11-2-2) plane seeds showed the highest growth rate. Semipolar (10-12)/(10-1-2) plane seeds also showed a high growth rate; however, the (10-12) plane was unstable during the growth process, in that a (10-11) facet partially appeared. On the other hand, nonpolar (10-10)/(10-10) seeds showed a lower growth rate, which indicates the stability of this plane. A (11-20) a-plane disappeared and changed into a (10-10) m-plane during growth. A Ga-face/N-face grown crystal showed a relatively high growth rate; however, poor crystal quality was confirmed by XRD (x-ray diffraction) measurement. Also, an extremely rough surface of the Ga-face grown crystal can be observed by an optical microscope.

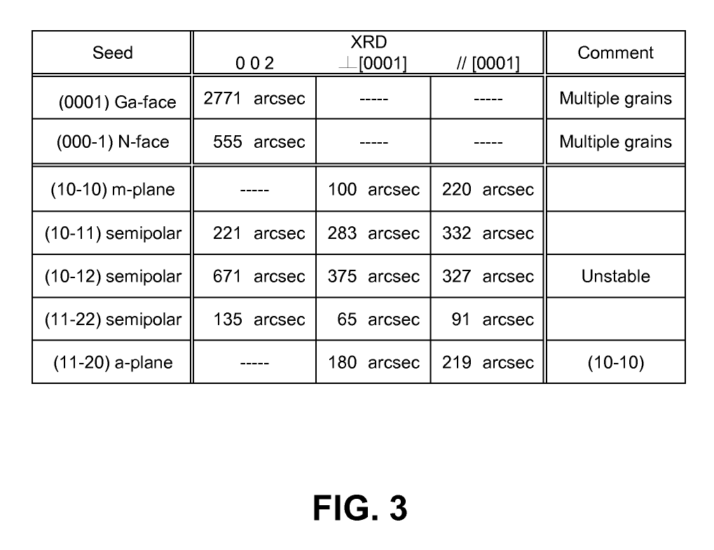

FIG. 3 is a table that shows XRD rocking curve FWHM (full width at half maximum) data for each of the crystals grown on the seed crystals. All the seed crystals mentioned here were polished and have atomically smooth surfaces, with an RMS roughness less than 1 nm. The nonpolar/semipolar planes showed evidence of a high crystal quality; however, the c-plane crystals showed evidence of poor crystal quality, even though grown from an atomically smooth surface (multiple grains and broader XRD curve FWHM's are evidence of poorer crystal quality). Further, the 2771 arcseconds of roughness on the (0001) planar growth, and the multiple grains that are present on both the (0001) and (000-1) planes of growth, indicate that growth of these planes using a solvothermal method, e.g., the ammonothermal method, is likely to produce a surface that is unacceptable for device fabrication, for mechanical reasons, electrical property reasons, and/or other reasons. However, the present invention shows that semi-polar growth rates and relative smoothness of the semi-polar film surfaces, made via the same solvothermal methods as the unacceptable polar films, result in semi-polar surfaces that are “device quality,” e.g., would be useable to make a working device.

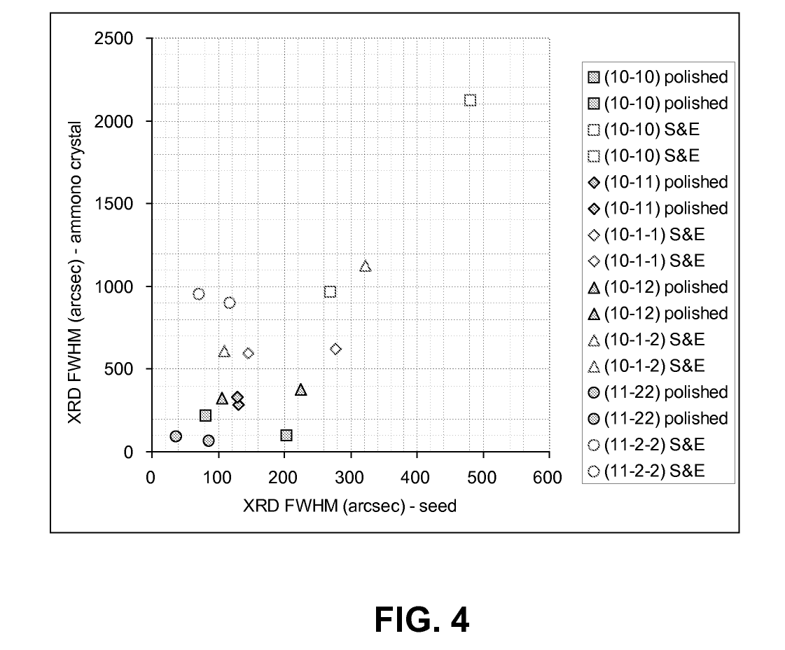

FIG. 4 is a graph that shows the correlation between the on-axis XRD FWHM data of each seed surface and the on-axis XRD FWHM data of the obtained crystal. A seed with a small FWHM does not necessarily make small FWHM crystals. Moreover, a sliced and etched seed surface causes worse FWHM values for the resulting crystals.

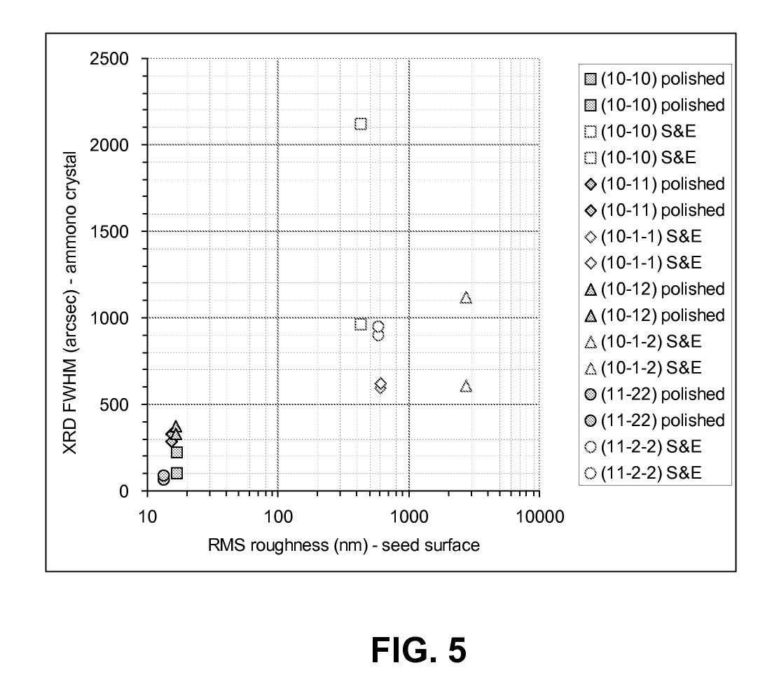

FIG. 5 is a graph that shows the correlation between the RMS roughness of each seed surface and the on-axis XRD FWHM data of the resulting crystals. The RMS roughness is measured by a step height measurement system. The smooth seed surface results in better crystal quality. Microscopically, various direction growths occur on the rough seed surface, and the FWHM becomes wide.

In some bulk crystal growth, the etching off of the seed surface, slightly and just before the growth, is common and effective. The purpose of the etch is to remove the damaged layer, or to make the seed surface smooth, or to “wash” the impurities from the seed surface. However, it does not appear to be effective with supercritical ammonia and GaN; at least, the etching by supercritical ammonia cannot make a rough GaN surface smooth.

Experimental Results for Off-Orientations

In one embodiment of the present invention, various off-oriented seed crystals were loaded in the same growth process. The present invention has investigated on-axis (10-10) m-plane seed crystals and seed crystals having the following off-orientations from the on-axis (10-10) m-plane: 2 degrees towards c+/c−, 5 degrees towards c+/c−, 28 degrees towards c+/c− (10-11)/(10-1-1), 47 degrees towards c+/c− (10-12)/(10-1-2), and 90 degrees towards c+/c− (0001)/(000-1).

The seed crystals were grown in the [0001] direction using an HVPE method and sliced into wafer shapes having the desired off-orientations mentioned above. The off-orientation tolerance of the seed wafers was +0.5/−0.5 degrees.

This embodiment of the present invention has performed 4 growth experiments under similar conditions, as mentioned above.

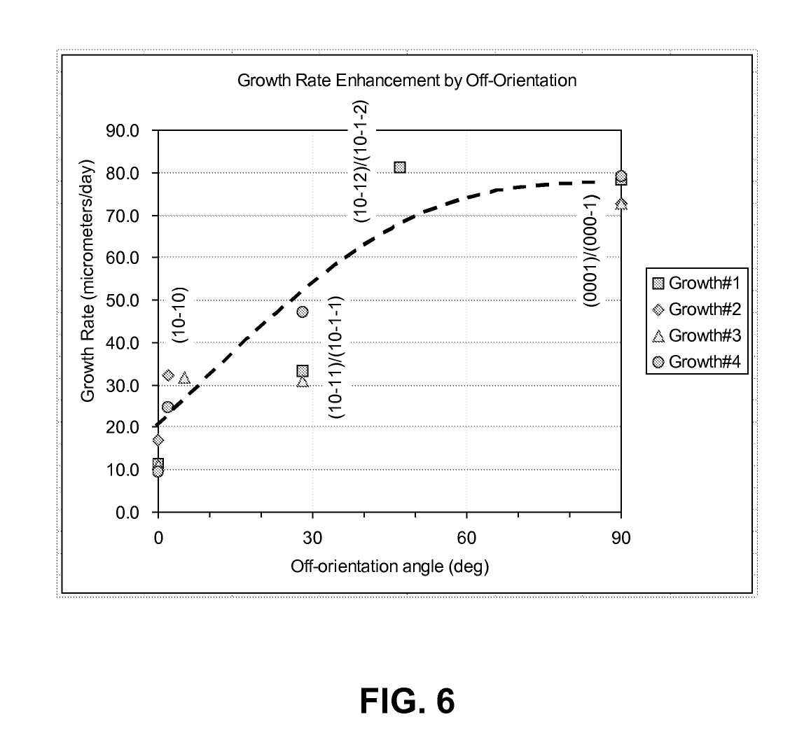

FIG. 6 shows the off-orientation dependence of growth rates. The growth rate strongly depends on the off-orientation angles. Larger off-orientation seed crystals show higher growth rates, up to 8 times higher than on-axis (10-10) m-plane seeds.

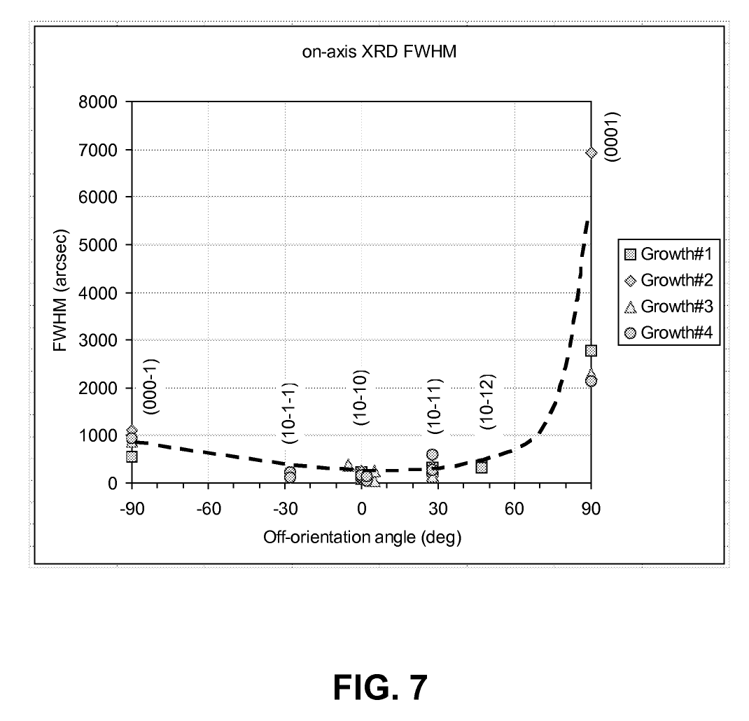

FIG. 7 shows XRD rocking curve FWHM data for each off-oriented seed crystal. −90 to 48 degrees off-oriented seed crystals showed similar crystal quality. On the other hand, (0001) crystals showed much larger FWHM.

Higher growth rate can be achieved without losing crystal quality by using off-oriented seed crystals.

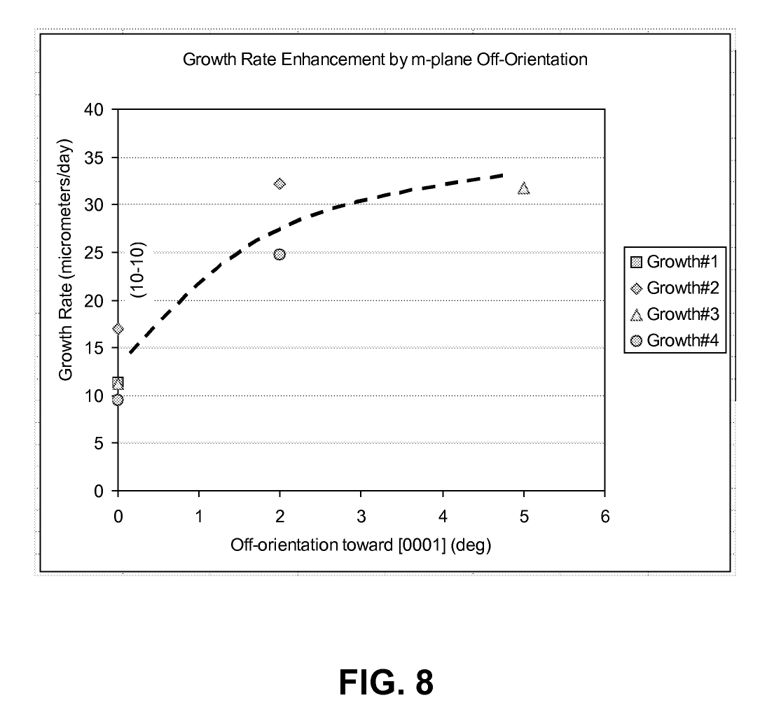

FIG. 8 is the 0-5 degree range close-up of FIG. 6. This shows that even a little off-orientation, such as 2 degrees or 5 degrees, can cause around 3 times higher growth rate.

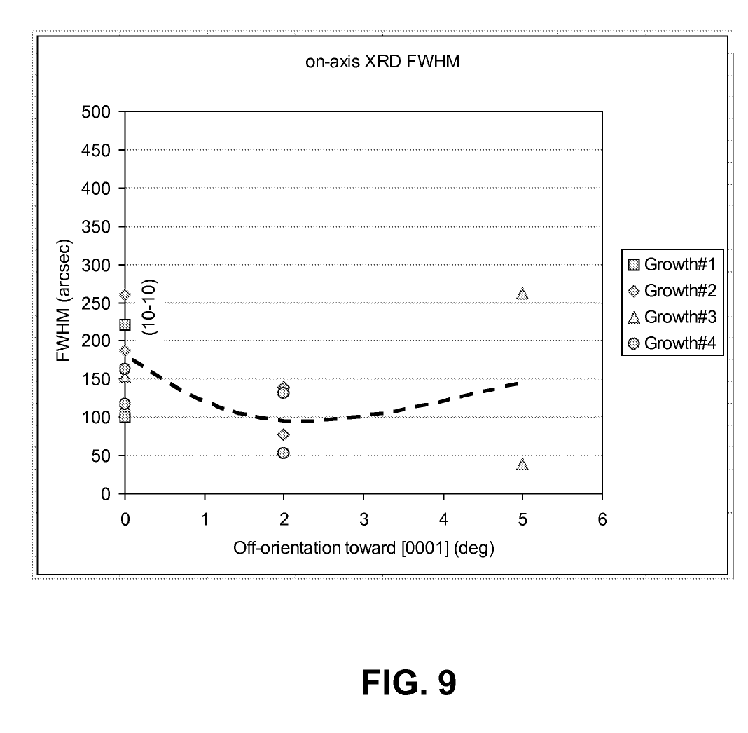

FIG. 9 is the 0-5 degree range close-up of FIG. 7. This shows that the crystal quality becomes best when the off-orientation is between 0 degrees and 5 degrees.

The highest crystal quality can be achieved by using slightly off-oriented seed crystals.

Possible Modifications and Variations

In addition to the GaN growth in supercritical ammonia described above, the technique of the present invention is applicable to other III-nitride crystals, such as AN, InN, etc. Moreover, the technique of the present invention is applicable to hexagonal crystals grown by a hydro-thermal method, such as ZnO, etc.

Although on-axis nonpolar and semipolar seed crystals were used, any misoriented wafers from those planes are also applicable. Although the present invention used m-planes seed crystals with off-orientation toward the c+/c-direction, off-orientation toward the a-direction or another direction is also applicable.

It is reasonable to consider that poorer quality crystals contain higher impurities as compared to higher quality crystals prepared under the same/similar growth conditions as the poorer quality crystals. Lower impurity incorporation rate is expected using nonpolar/semipolar seed crystals as compared to Ga-face or N-face seed crystals.

It has been found that nonpolar/semipolar plane crystals are higher quality as compared to c-plane crystals. The present invention has also found that crystals grown on slightly off-oriented m-plane seeds are higher quality than crystals grown on on-axis m-plane seeds. The reason for this may not be the growth method, but the nature of the hexagonal crystal structure. Therefore, the present invention may be widely applicable to other growth techniques, such as vapor phase growth, etc.

Solvothermal growth is growth by supercritical fluid. Solvothermal growth includes hydrothermal growth and ammonthermal growth, for example. The present invention also envisages hydrothermal growth of ZnO crystals, for example.

Advantages and Improvements

High crystal quality c-plane crystals fabricated with a low growth rate using supercritical ammonia has been reported [1]. In the present invention, it was confirmed that the same or better XRD FWHM can be achieved by using nonpolar/semipolar plane seed crystals with a growth rate that is more than 10 times higher. With the higher growth rate conditions, c-plane grown crystal quality was worse, as shown in XRD-FWHM data. It was confirmed that a high growth rate is achievable at the same time as high crystal quality by choosing suitable growth planes.

In the present invention, it was also confirmed that a superior XRD FWHM can be achieved by using slightly off-oriented m-plane seed crystals, and with around 5 times higher growth rate as compared to using m-plane seed crystals that have not been off-cut. The quality of c-plane grown crystal is worse, as shown in XRD-FWHM data. It was confirmed that a high growth rate and a high crystal quality is achievable at the same time by choosing suitable off-orientation angles.

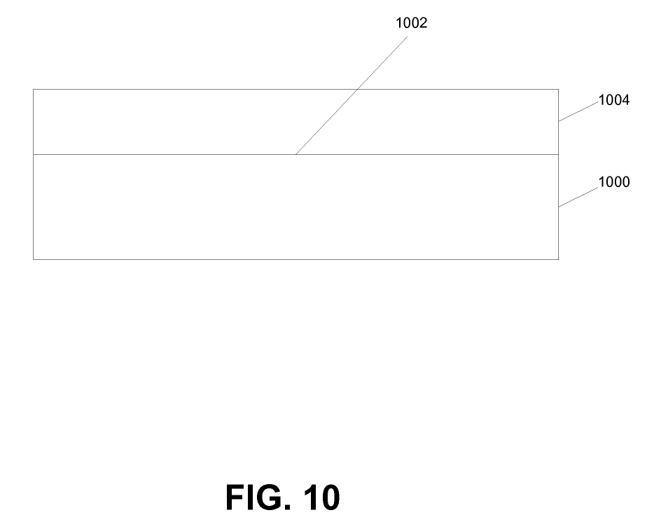

FIG. 10 illustrates a growth in accordance with one or more embodiments of the present invention.

Seed crystal 1000 is shown, with growth surface 1002. Seed crystal 1000 is typically a hexagonal würtzite crystal, and typically a Group III-nitride structure. As discussed hereinabove, growth surface 1002 is a non-polar or semi-polar plane of the seed crystal 1000. Further, growth surface 1002 can be an off-oriented m-plane of the seed crystal 1000, or an off-oriented plane from any of the planes of the seed crystal 1000. Layer 1004 is grown on growth surface 1002, via a solvo-thermal method, which is typically an ammonothermal method. Since the growth planes grow at different growth rates, and the grown material on each plane have different qualities, e.g., electrical properties, surface smoothness, etc., the growth plane can be selected to match the device requirements, time available, and the costs. So, for example, and not by way of limitation, a growth surface 1002 on seed crystal 1000 can be selected to maximize the growth rate of layer 1004, to maximize the surface smoothness of the layer 1004, or some other property desired in layer 1004 can be designed by selecting different growth surfaces 1002 on seed crystal 1000.

### REFERENCES

The following references are incorporated by reference herein:
[1] Hashimoto et al., Nat. Mater. 6 (2007) 568.
[2] European Patent Application Publication No. EP 1 816 240 A1, entitled “Hexagonal Wurtzite Single Crystal, Process for Producing the same, and Hexagonal Wurtzite Single Crystal Substrate,” filed Sep. 21, 2005.

### CONCLUSION

The present invention describes crystals and methods for growing crystals. A single bulk crystal in accordance with the present invention comprises a hexagonal würtzite structure, wherein the single bulk crystal is grown via solvo-thermal growth using a seed having a nonpolar or semipolar plane.

Such a crystal further optionally comprises the single bulk crystal being a III-nitride, the seed for the crystal having a growth surface comprising at least one of the following planes: {10-10}, {10-11}, {10-1-1}, {10-12}, {10-1-2}, {11-20}, {11-22} or {1′-2-2}, the seed for the crystal having a growth surface comprising an m-plane with an off-orientation angle, the off-orientation angle being toward a [0001] direction and the off-orientation angle being larger than 0.5 degrees and less than or equal to 48 degrees, the off-orientation angle being toward the [0001] direction and being larger than 0.5 degrees and less than 4.5 degrees, the off-orientation angle being toward a [000-1] direction, and larger than 0.5 degrees and less than 90 degrees, a root mean square (RMS) roughness of a growth surface of the seed being less than 100 nm, an x-ray diffraction (XRD) rocking curve full-width-at-half-maximum (FWHM) for the bulk crystal being smaller than 500 arcsec, the single bulk crystal being gallium nitride, and the single bulk crystal being cut to obtain a substrate.

A method of growing a single bulk crystal with a hexagonal würtzite structure in accordance with one or more embodiments of the present invention comprises performing solvo-thermal crystal growth on a seed crystal having a growth surface comprising a nonpolar plane or a semipolar plane.

Such a method further optionally comprises the single bulk crystal being a III-nitride, the growth surface comprising at least one of the following planes: {10-10}, {10-11}, {10-1-1}, {10-12}, {10-1-2}, {11-20}, {11-22} or {11-2-2}, the growth surface comprising an m-plane with an off-orientation angle, the off-orientation angle being toward a [0001] direction, larger than 0.5 degrees and less than or equal to 48 degrees, the off-orientation angle being toward the [0001] direction, is larger than 0.5 degrees and less than 4.5 degrees, the off-orientation angle being toward a [000-1] direction, is larger than 0.5 degrees and less than 48 degrees, a root mean square (RMS) roughness of the growth surface being less than 100 nm, an x-ray diffraction (XRD) rocking curve full-width-at-half-maximum (FWHM) for the bulk crystal being smaller than 500 arcsec, the bulk crystal being a gallium nitride, and the crystal being cut to obtain a substrate.

Another method of fabricating a III-nitride bulk crystal or device in accordance with one or more embodiments of the present invention comprises growing the III-nitride bulk crystal or device on a growth surface of a seed, wherein the growth surface comprises one or more nonpolar or semipolar planes, or one or more off-orientations of the nonpolar or semipolar planes, and using the growing, which is in a nonpolar, semipolar or off-oriented direction, to increase a quality, growth rate, or both a quality and growth rate, of the III-nitride bulk crystal or device.

Another method of making a III-nitride crystal in accordance with one or more embodiments of the present invention comprises growing a III-nitride bulk crystal via a solvo-thermal method, wherein the III-nitride bulk crystal is grown in a growth plane other than a c-plane, wherein the growth plane is selected based on at least one of a growth rate in the growth plane and a quality of growth in the growth plane.

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching without fundamentally deviating from the essence of the present invention. It is intended that the scope of the invention be limited not by this detailed description, but rather by the claims appended hereto and the full range of equivalents to the claims appended hereto.

What is claimed is:

1. A single bulk crystal comprising a hexagonal würtzite structure, wherein the single bulk crystal is grown via solvo-thermal growth using a seed having a nonpolar or semipolar plane.

2. The single bulk crystal of claim 1, wherein the single bulk crystal is a III-nitride.

3. The crystal of claim 1, wherein the seed for the crystal has a growth surface comprising at least one of the following planes: {10-10}, {10-11}, {10-1-1}, {10-12}, {10-1-2}, {11-20}, {11-22} or {11-2-2}.

4. The single bulk crystal of claim 1, wherein the seed for the crystal has a growth surface comprising an m-plane having an off-orientation angle.

5. The single bulk crystal of claim 4, wherein the off-orientation angle is toward a [0001] direction, and the off-orientation angle is larger than 0.5 degrees and less than or equal to 48 degrees.

6. The single bulk crystal of claim 5, wherein the off-orientation angle is toward the [0001] direction, is larger than 0.5 degrees and is also less than 4.5 degrees.

7. The single bulk crystal of claim 4, wherein the off-orientation angle is toward a [000-1] direction, is larger than 0.5 deg. and is also less than 90 degrees.

8. The single bulk crystal of claim 1, wherein a root mean square (RMS) roughness of a growth surface of the seed is less than 100 nm.

9. The single bulk crystal of claim 1, wherein an x-ray diffraction (XRD) rocking curve full-width-at-half-maximum (FWHM) for the bulk crystal is smaller than 500 arcsec.

10. The single bulk crystal of claim 1, wherein the bulk crystal is gallium nitride.

11. The single bulk crystal of claim 1, wherein the bulk crystal is cut to obtain a substrate.

12. A method of growing a single bulk crystal with a hexagonal würtzite structure, comprising:
performing solvo-thermal crystal growth on a seed crystal having a growth surface comprising a nonpolar plane or a semipolar plane.

13. The method of claim 12, wherein the single bulk crystal is a III-nitride.

14. The method of claim 12, wherein the growth surface comprises at least one of the following planes: {10-10}, {10-11}, {10-1-1}, {10-12}, {10-1-2}, {11-20}, {11-22} or {11-2-2}.

15. The method of claim 12, wherein the growth surface comprises an m-plane having an off-orientation angle.

16. The method of claim 15, wherein an off-orientation angle is toward a [0001] direction, is larger than 0.5 degrees and is also 48 degrees or less.

17. The method of claim 16, wherein the off-orientation angle is toward the [0001] direction, is larger than 0.5 degrees and is also less than 4.5 degrees.

18. The method of claim 15, wherein the off-orientation angle is toward a [000-1] direction, is larger than 0.5 degrees and is also less than 48 degrees.

19. The method of claim 12, wherein a root mean square (RMS) roughness of a growth surface of the seed is less than 100 nm.

20. The method of claim 12, wherein an x-ray diffraction (XRD) rocking curve full-width-at-half-maximum (FWHM) for the bulk crystal is smaller than 500 arcsec.

21. The method of claim 12, wherein the bulk crystal is a gallium nitride.

22. The method of claim 12, wherein the crystal is cut to obtain a substrate.

23. A method of fabricating a III-nitride bulk crystal or device, comprising:
(a) growing the III-nitride bulk crystal or device on a growth surface of a seed, wherein the growth surface comprises one or more nonpolar or semipolar planes, or one or more off-orientations of the nonpolar or semipolar planes, and
(b) using the growing, which is in a nonpolar, semipolar or off-oriented direction, to increase a quality, a growth rate, or both the quality and the growth rate, of the III-nitride bulk crystal or device.

24. A method of making a III-nitride crystal, comprising:
growing a III-nitride bulk crystal via a solvo-thermal method, wherein the III-nitride bulk crystal is grown in a growth plane other than a c-plane, wherein the growth plane is selected based on at least one of a growth rate in the growth plane and a quality of growth in the growth plane.
